(19) United States
(12) Patent Application Publication
(10) Pub. No.: US 2011/0101494 A1
(43) Pub. Date: May 5, 2011

(54) SEMICONDUCTOR MEMORY DEVICE

(76) Inventor: Jong-Su KIM, Gyeonggi-do (KR)

(21) Appl. No.: 12/915,694

(22) Filed: Oct. 29, 2010

(30) Foreign Application Priority Data
Oct. 30, 2009 (KR) 10-2009-0104680

(51) Int. Cl. H01L 23/525

(52) U.S. Cl. 257/529; 257/E23.149

(57) ABSTRACT

A semiconductor memory device includes: a first bit line contact pattern coupled to a region of a word line conductive layer; a first bit line conductive pattern coupled to the first bit line contact pattern; a first metal interconnection contact pattern coupled to the first bit line conductive pattern; a fuse having a side coupled to the first metal interconnection contact pattern; a second bit line contact pattern coupled to another region of the word line conductive layer; a second bit line conductive pattern coupled to the second bit line contact pattern; a second metal interconnection contact pattern coupled to the second bit line conductive pattern; and a first guard ring metal layer disposed on the same layer as the first and second metal interconnection contact patterns and between the first and second metal interconnection contact patterns and disposed as a layer surrounding the fuse.

### CROSS-REFERENCE TO RELATED APPLICATIONS

The present application claims priority of Korean Patent Application No. 10-2009-0104680, filed on Oct. 30, 2009, which is incorporated herein by reference in its entirety.

### BACKGROUND OF THE INVENTION

Exemplary embodiments of the present invention relate to a semiconductor memory device, and more particularly, to a fuse of a semiconductor memory device and a guard ring of the fuse.

In the fabrication of a semiconductor device such as a memory device, when a defect occurs in a memory cell, the entire memory device may be discarded as a defective product because the corresponding memory device cannot perform a memory function. If the entire memory device is discarded as a defective product even when a defect occurs in just few memory cells, yield loss occurs.

To increase the yield of a semiconductor memory device, defective cells are replaced with redundancy cells within the semiconductor memory device. The repair process using the redundancy cells is often performed by replacing normal word lines with redundancy word lines coupled to redundancy cells and normal bit lines with redundancy bit lines coupled to redundancy bit cells. More specifically, when defective cells are detected through a test after a wafer processing, a program for changing addresses corresponding to the defective cells into addresses corresponding to the redundancy cells is executed in an internal circuit. Therefore, when an address signal corresponding to a defective cell is inputted, data of a redundancy cell replacing the defective cell is accessed.

In implementing the above-described defective memory cell replacement method, an address path is often changed by blowing a fuse with a laser beam. Therefore, a semiconductor memory device often includes a fuse unit which can change an address path by irradiating a laser beam onto a fuse to thereby blow the fuse. Here, the fuse unit includes a plurality of fuse sets, where each fuse set can replace an address path. The number of fuse sets provided in the fuse unit is determined by the number of redundancy word lines or redundancy bit lines, where the redundancy word lines or redundancy bit lines are provided according to the spare area of the semiconductor memory device. Each fuse set includes a plurality of address fuses, and a defective address path is replaced by selectively blowing the plurality of address fuses.

The fuse unit includes a fuse guard ring for protecting an internal circuit from foreign particles introduced through fuses and fuse regions. The fuse guard ring is generally formed using a metal layer, where there is a concern that a leakage signal is transferred through the metal layer.

### SUMMARY OF THE INVENTION

An exemplary embodiment of the present invention is directed to a semiconductor memory device including a guard ring in a fuse region in order to substantially prevent a signal leakage.

In accordance with an exemplary embodiment of the present invention, a semiconductor memory device includes: a first bit line contact pattern coupled to a region of the word line conductive layer; a first bit line conductive pattern coupled to the first bit line contact pattern; a first metal interconnection contact pattern coupled to the first bit line conductive pattern; a fuse having a side coupled to the first metal interconnection contact pattern; a second bit line contact pattern coupled to another region of the word line conductive layer; a second bit line conductive pattern coupled to the second bit line contact pattern; a second metal interconnection contact pattern coupled to the second bit line conductive pattern; and a first guard ring metal layer disposed on the same layer as the first and second metal interconnection contact patterns and between the first and second metal interconnection contact patterns and disposed as a layer surrounding the fuse.

The first guard ring metal layer may maintain a floating state.

The semiconductor memory device may further include a first metal pattern coupled to the upper portion of the second metal interconnection contact pattern and disposed as a conductive layer constituting the same layer as the fuse.

The semiconductor memory device may further include a third bit line conductive pattern disposed on the same layer as the first and second bit line conductive patterns and coupled to the lower portion of the first guard ring metal layer.

The semiconductor memory device may further include a second metal layer coupled to the upper portion of the first guard ring metal layer and disposed as a conductive layer on the same layer as the fuse.

The semiconductor memory device may further include: a third metal interconnection contact pattern coupled to the upper portion of the second guard ring metal layer; and a second metal pattern coupled to the upper portion of the third metal interconnection contact pattern.

The first and second bit line contact patterns may each have a rectangular or circular cross-section.

In accordance with another exemplary embodiment of the present invention, a semiconductor memory device includes: a fuse; a first metal interconnection contact pattern coupled to a side of the fuse; a word line conductive layer electrically coupled to the first metal pattern; a second metal interconnection contact pattern electrically coupled to the word line conductive layer; and a third metal interconnection contact pattern arranged between the first and second metal interconnection contact patterns, wherein the third metal interconnection contact pattern is not coupled to the word line conductive layer and is arranged to float in voltage.

### BRIEF DESCRIPTION OF THE DRAWINGS

FIG. 1 is a cross-sectional view of a fuse unit of a semiconductor memory device.

FIG. 2 is a plan view of the fuse unit illustrated in FIG. 1.

FIG. 3 is a plan view of a fuse unit in accordance with an exemplary embodiment of the present invention.

FIG. 4 is a cross-sectional view of the fuse unit in accordance with an exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

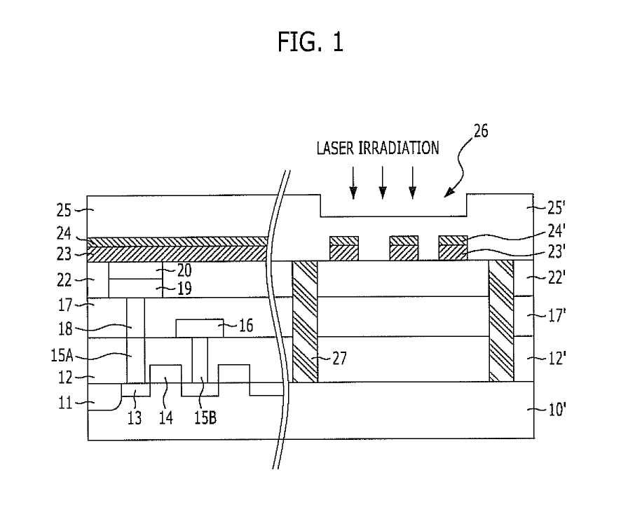

FIG. 1 is a cross-sectional view of a semiconductor memory device. In FIG. 1, the left region of the semiconductor memory device represents a cross section of a cell region, and the right region represents a fuse region.

Referring to FIG. 1, the cell region of the semiconductor memory device includes an isolation layer 11, an active region 13, a gate pattern 14, first and second storage node contact plugs 15A and 18, a bit line contact plug 15B, a bit line 16, interlayer dielectric layers 12, 17, 22 and 25, a storage node contact plug 19, a dielectric thin film 20, and plate electrodes 23 and 24, which are formed on a substrate 10′. The storage node contact plug 19, the dielectric thin film 20, and the plate electrodes 23 and 24 constitute a capacitor. The plate electrodes 23 and 24 include a polysilicon layer 23 and a TiN layer 24.

Meanwhile, the fuse region of the semiconductor memory device includes interlayer dielectric layers 12, 17′ and 22′ on the substrate 10′, a fuse including a polysilicon layer 23′ and a TiN layer 24′, an interlayer dielectric layer 25′ on the fuse, and a guard ring 27 for substantially preventing penetration of moisture. Also, reference numeral 26 represents a fuse box formed by removing the interlayer dielectric layer 25′ on the fuse to a desired depth in blowing fuse during a repair process. According to an example, the interlayer dielectric layers 12′, 17′ and 22′ and the fuse 23′ and 24′ are formed at times that the interlayer dielectric layers 12, 17 and 22 of the cell region and the plate electrodes 23 and 24 of the capacitor are formed, respectively.

Thus, the fuse 23′ and 24′ is provided for repairing a defective region of the semiconductor memory device. According to an example, the fuse 23′ and 24′ is not separately formed using an additional process and is formed by using a conductive layer (for example, polysilicon) constituting a bit line or a word line of the cell region.

However, as the integration density of the semiconductor memory device increases, the structure of the semiconductor memory device may become larger in height. Thus, when the fuse 23′ and 24′ is formed using the word line or the bit line that form lower structures of the semiconductor memory device, subsequent formation of a fuse box may be performed by removing a large number of interlayer dielectric layers. Therefore, according to an example, a conductive layer formed on a higher position of the semiconductor memory device is used as a fuse line. More specifically, a metal interconnection or a conductive layer for a plate electrode of a capacitor may be used as a fuse line. The fuse 23′ and 24′ illustrated in FIG. 1 may be formed using a conductive layer which forms the plate electrodes 23 and 24 of the capacitor formed in the cell region. As stated above, in the fabrication of a semiconductor memory device, the height from the substrate to the uppermost layer may be great. Thus, the fuse 23′ and 24′ may formed using a metal interconnection layer.

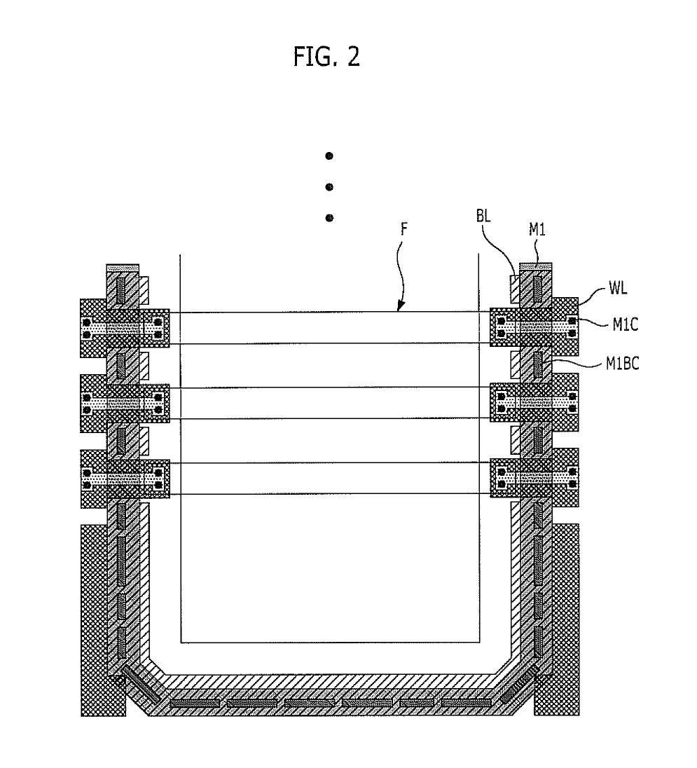

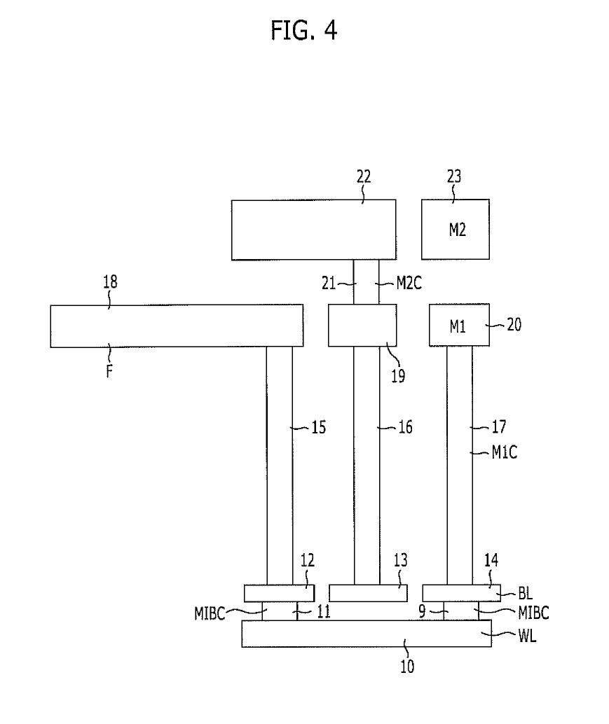

FIG. 2 is a plan view of a fuse unit illustrated in FIG. 1. A cross section of a fuse unit that includes a fuse F and a guard ring (e.g., M1C and M1BC) surrounding the fuse F is shown in FIG. 4.

Referring to FIG. 2, the fuse F is disposed in a fuse region. One or more conductive layers may be formed through a separate process for forming a conductive layer in a cell array region or through a same process that the fuse is formed in the fuse region. A guard ring (e.g., M1C and M1BC) is disposed around the fuse F in such a manner that the guard ring surrounds the fuse F. The fuse region may be further etched than other regions of the semiconductor memory device in blowing the fuse by laser irradiation. The guard ring is formed in order to substantially prevent foreign particles from being introduced to other regions of the semiconductor device through the etched space. As illustrated in FIG. 2, the fuse F is disposed within the guard ring. A word line conductive layer WL and a bit line conductive layer BL are disposed as illustrated in FIG. 2. The fuse F is coupled to the word line conductive layer WL through contact M1C.

In FIG. 2, the guard ring is formed using the bit line conductive layer BL and first metal M1, and the fuse F is formed using a second metal. In the guard ring, the bit line conductive layer BL is disposed with a plurality of patterns as illustrated in FIG. 2.

Here, when an error occurs in a cell, an address path for the defective cell is replaced by using the fuse so that a redundancy cell is accessed instead. In this manner, a normal operation for accessing a cell is achieved even if the cell is defective. As described above, the guard ring is formed in the fuse region such that the guard ring surrounds the fuse F in order to prevent the fuse F from affecting a neighboring circuit. As illustrated in FIG. 2, in the guard ring, a metal interconnection layer and a contact pattern are alternately formed. A bias is applied to the guard ring.

Since the fuse region for laser irradiation is relatively narrow and the height of other pattern layers formed over the fuse is relatively great, the fuse guard ring is formed using a plurality of patterns. However, foreign particles may be introduced into regions between the contact pattern and the metal interconnection layer and cause a leakage current to occur. After the fuse F is blown by laser irradiation, signals are not to be transferred through the fuse. However, signals may transfer through the blown fuse when leakage current occurs. If such an event occurs, since an accurate the is address of the repaired cell may not be known and an error may occur in data access.

To prevent such an occurrence of an error, according to an exemplary embodiment of the invention, the signal is transferred to the fuse F1 through a pattern disposed on the same layer as a gate pattern, and the guard ring is formed using the bit line metal layer and the contact metal pattern in a cylindrical shape. Further, by applying no bias to the guard ring (e.g., the first guard ring metal layer 16 in FIG. 4), the semiconductor memory device floats in voltage. Thus, according to an exemplary embodiment of the present invention, a semiconductor memory device uses a metal fuse and forms a guard ring around the metal fuse in a cylindrical shape.

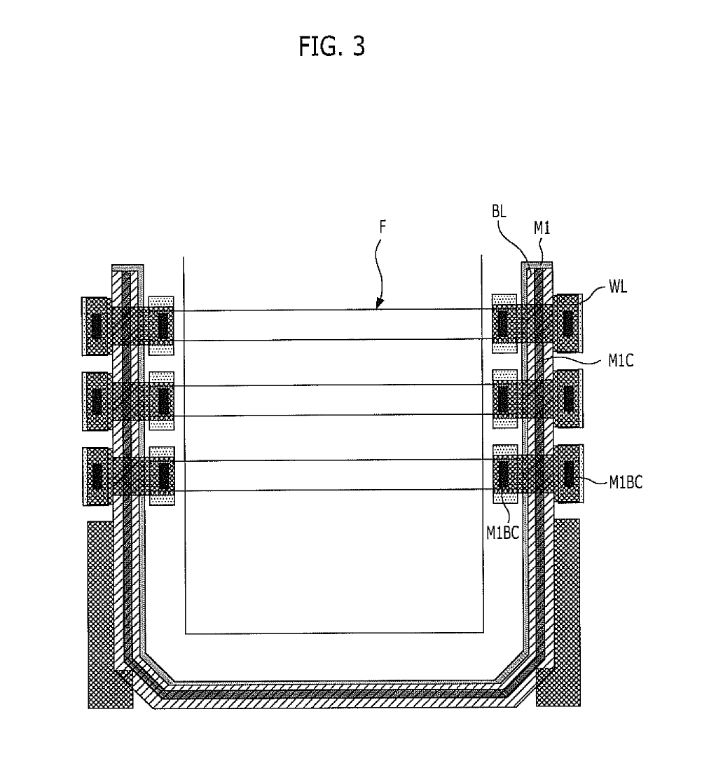

FIG. 3 is a plan view of a fuse unit in accordance with an exemplary embodiment of the present invention. A cross section of a fuse unit that includes a fuse F and a guard ring (e.g., M1C and M1BC) surrounding the fuse F is shown in FIG. 4.

Referring to FIG. 3, a fuse unit of the semiconductor memory device in accordance with an exemplary embodiment of the present invention includes a fuse F formed using a metal interconnection conductive layer, a word line conductive layer WL, a bit line contact pattern M1BC, an bit line conductive layer BL, and a contact pattern M1C. The bit line conductive layer BL formed on both ends of the word line conductive layer WL surrounds the vicinity of the fuse F. A contact M1C is formed using the bit line contact layer BL as a buffer layer.

FIG. 4 is a cross-sectional view of the fuse unit in accordance with an exemplary embodiment of the present invention. In FIG. 4, a reference label is assigned to each pattern, and the patterns formed on the same layer are collectively represented by a reference label to the right side of the element (e.g., MIC).

Referring to FIG. 4, in the fuse unit of the semiconductor memory device in accordance with an exemplary embodiment of the present invention, bit line contact patterns 11 and 9 are formed on a word line conductive layer 10, and bit line conductive layers 12, 13 and 14 are formed on the bit line contact patterns 11 and 9. Contact patterns 15, 16 and 17 are formed on the bit line contact layers 12, 13 and 14. Metal interconnection conductive layers 18, 19 and 20 are formed on the contact patterns 15, 16 and 17, and a contact pattern 21 is formed on the metal interconnection conductive layers 18, 19 and 20. Metal interconnection conductive layers 22 and 23 are formed on the contact pattern 21. The fuse F is formed using a metal interconnection conductive layer 18. The conductive layer 10 is a word line conductive layer WL, and the bit line contact patterns 11 and 9 are bit line contacts M1BC. The conductive layers 12, 13 and 14 are bit line contact conductive layers. The contacts 15, 16 and 17 are patterns using a contact M1C for coupling the first metal interconnection and the bit line. The conductive layers 18, 19 and 20 use the first metal interconnection M2. The conductive layers 22 and 23 use interconnections disposed on the same layer as the second metal interconnection M2. The contact pattern 21 uses a pattern disposed on the same layer as the contact coupling the first metal interconnection and the second metal interconnections M1 and M2. In addition, the conductive layer 18 is implemented as the fuse.

More specifically, the fuse unit of the semiconductor memory device in accordance with the exemplary embodiment of the present invention includes the word line conductive layer 10, the first bit line contact pattern 11 coupled to a region of the word line conductive layer 10, the first bit line conductive pattern 12 coupled to the first bit line contact pattern 11, the first metal interconnection contact pattern 15 coupled on the first bit line conductive pattern 12, the fuse F having a side coupled to the first metal interconnection contact pattern 15, the second bit line contact pattern 9 coupled to the opposite region of the word line conductive layer 10, the second bit line conductive pattern 14 coupled to the second bit line contact pattern 9, the first guard ring metal layer 16 disposed on the same layer as the first and second metal interconnection contact patterns 15 and 17 and between the first and second metal interconnection contact patterns 15 and 17 and disposed as a single layer surrounding the fuse F, and the second metal interconnection contact pattern 17 coupled to the second bit line conductive pattern 14.

Also, in the fuse unit of the semiconductor memory device in accordance with the exemplary embodiment of the present invention, the first guard ring metal layer 16 maintains a floating state. Furthermore, the fuse unit of the semiconductor memory device in accordance with the exemplary embodiment of the present invention further includes a first metal pattern 20 coupled to the upper portion of the second metal interconnection contact pattern 17 and disposed as a conductive layer on the same layer as the fuse F.

Moreover, the fuse unit of the semiconductor memory device in accordance with the exemplary embodiment of the present invention further includes a third bit line conductive pattern 13 disposed on the same layer as the first and second bit line conductive patterns 12 and 14 and coupled to the lower portion of the first guard ring metal layer.

Also, the fuse unit of the semiconductor memory device in accordance with the exemplary embodiment of the present invention further includes a second guard ring metal layer 19 coupled to the upper portion of the first guard ring metal layer 16 and disposed as a conductive layer on the same layer as the fuse F.

Furthermore, the fuse unit of the semiconductor memory device in accordance with the exemplary embodiment of the present invention further includes a third metal interconnection contact pattern 21 coupled to the upper portion of the second guard ring metal layer 19, and a second metal pattern 22 coupled to the upper portion of the third metal interconnection contact pattern 21.

As illustrated, the fuse F is coupled to the contact 15 and is coupled to the bit line conductive layer 12, the contact 11, and the word line conductive layer 10 through the contact 15. The word line conductive layer 10 is not coupled to one (contact 16) of the contacts M1C that constitute the guard ring. Also, the word line conductive layer 10 is coupled to the bit line contact 9. The bit line conductive layers 12, 13 and 14 serve as a buffer layer when the contacts 15, 16 and 17 constituting the guard ring are formed.

The fuse unit of the semiconductor memory device in accordance with the exemplary embodiment of the present invention transfers the signal of the fuse through the gate conductive layer. Also, the guard ring is formed in a cylindrical shape by forming the metal line and the contact on the bit line conductive layer. By applying no bias to the guard ring, the guard ring is in a floating state, thereby reducing the possibility of a leakage current.

Moreover, the bit line contact formed in the fuse use of the semiconductor memory device is formed to have a rectangular or circular cross-section. While the fuse formed using the first metal interconnection conductive layer is illustrated, according to another embodiment, the fuse may be formed using the second metal interconnection conductive layer.

In accordance with exemplary embodiments of the present invention, a signal transfer between a blown fuse and its adjacent guard ring may be prevented/reduced. Furthermore, since the guard ring is disposed around the fuse in a form of a single layer to completely surround the fuse, a signal transfer by the fuse guard ring formed with a plurality of segments may be prevented/reduced.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device comprising:
a word line conductive layer;
a first bit line contact pattern coupled to a region of the word line conductive layer;
a first bit line conductive pattern coupled to the first bit line contact pattern;
a first metal interconnection contact pattern coupled to the first bit line conductive pattern;
a fuse having a side coupled to the first metal interconnection contact pattern;
a second bit line contact pattern coupled to another region of the word line conductive layer;
a second bit line conductive pattern coupled to the second bit line contact pattern;
a second metal interconnection contact pattern coupled to the second bit line conductive pattern; and
a first guard ring metal layer disposed on the same layer as the first and second metal interconnection contact patterns and between the first and second metal interconnection contact patterns and disposed as a layer surrounding the fuse.

2. The semiconductor memory device of claim 1, wherein the first guard ring metal layer is arranged to have a floating state.

3. The semiconductor memory device of claim 1, further comprising a first metal pattern coupled to the upper portion of the second metal interconnection contact pattern and disposed as a conductive layer constituting the same layer as the fuse.

4. The semiconductor memory device of claim 1, further comprising a third bit line conductive pattern disposed on the same layer as the first and second bit line conductive patterns and coupled to the lower portion of the first guard ring metal layer.

5. The semiconductor memory device of claim 4, further comprising a second metal layer coupled to the top of the first guard ring metal layer and disposed as a conductive layer constituting the same layer as the fuse.

6. The semiconductor memory device of claim 5, further comprising:
a third metal interconnection contact pattern coupled to the upper portion of the second guard ring metal layer; and
a second metal pattern coupled to the upper portion of the third metal interconnection contact pattern.

7. The semiconductor memory device of claim 1, wherein the first and second bit line contact patterns each have a rectangular or circular cross-section.

8. A semiconductor memory device comprising:
a fuse;
a first metal interconnection contact pattern coupled to a side of the fuse;
a word line conductive layer electrically coupled to the first metal pattern;
a second metal interconnection contact pattern electrically coupled to the word line conductive layer; and
a third metal interconnection contact pattern arranged between the first and second metal interconnection contact patterns, wherein the third metal interconnection contact pattern is not coupled to the word line conductive layer and is arranged to float in voltage.

9. The semiconductor memory device of claim 8, wherein the first and second metal interconnection contact patterns are coupled to the word line conductive layer through respective bit line conductive layers.
